(19) United States
(12) Patent Application Publication
(10) Pub. No.: US 2026/0106587 A1
(43) Pub. Date: Apr. 16, 2026

(54) OUTPUT AMPLIFIER CIRCUIT AND DISPLAY DRIVER

(71) Applicant: ROHM Co., Ltd., Kyoto (JP)

(72) Inventors: Hiroki AIZAWA, Kyoto (JP); Hiroshi TSUCHI, Kyoto (JP)

(73) Assignee: ROHM Co., Ltd., Kyoto (JP)

(21) Appl. No.: 19/352,471

(22) Filed: Oct. 8, 2025

(30) Foreign Application Priority Data
Oct. 16, 2024 (JP) 2024-180747

(51) Int. Cl. H03F 3/45; G09G 3/20

(52) U.S. Cl. CPC H03F 3/45475; G09G 3/2092; G09G 2310/08; G09G 2320/0626; G09G 2330/021

(57) ABSTRACT

An output amplifier circuit, includes: 1^{st} to K^{th} sub-bias circuits, provided respectively in correspondence with 1^{st} to K^{th} amplifier groups, K being an integer of 2 or more, obtained by dividing multiple amplifiers generating output voltages obtained by amplifying an input signal by using an operation current based on a high-power voltage; and a bias control circuit, transmitting, to each of the 1^{st} to K^{th} sub-bias circuits, a bias control signal indicating a voltage value of a bias voltage at a signal level based on a low-power voltage. Each sub-bias circuit includes: a level conversion circuit, obtaining a high voltage bias control signal converting the signal level of the bias control signal received by itself from the signal level based on the low-power voltage into the signal level based on the high-power voltage, and generates the bias voltage having a voltage value based on the high voltage bias control signal.

### CROSS-REFERENCE TO RELATED APPLICATION

This application claims the priority benefit of Japan application serial no. 2024-180747, filed on October 16, 2024. The entirety of the above-mentioned patent application is hereby incorporated by reference herein and made a part of this specification.

### BACKGROUND

### TECHNICAL FIELD

The disclosure relates to an output amplifier circuit and a display driver.

### DESCRIPTION OF RELATED ART

A display driver that drives a display panel such as a liquid crystal display panel or an organic EL panel includes multiple output amplifiers that amplify gradation voltages corresponding to brightness levels represented by a video signal and supply the voltages to source lines of the display panel.

Also, with the recent trend toward a large, high-definition screen among display panels, there is a demand for output amplifiers to have a shortened rise or fall time of the output voltage, i.e., a high slew rate. The output amplifier includes, for example, an operational amplifier, and can achieve high-speed response by increasing the slew rate through increasing the operation current flowing to the differential stage, however, an issue that the power consumption increases correspondingly arises.

Therefore, a display driver has been proposed that can adjust the magnitude of the operation current flowing to the differential stage of the output amplifier from the outside the output amplifier by using a bias voltage so that the magnitude of the operation current increases in the first half of one data period and decreases in the second half (e.g., see Japanese Patent Application Laid-open No. 2019-95545). In the display driver, multiple output amplifiers are divided into multiple groups, and a sub-bias circuit that generates a bias voltage is provided for each group. Each sub-bias circuit receives a reference current with a constant current value and also receives a bias control signal from a control unit, the bias control signal serving for controlling the voltage value of the bias voltage. Each sub-bias circuit generates multiple currents based on the reference current, and generates a desired synthesized current by combining the generated multiple currents in a combination according to the bias control signal. Then, each sub-bias circuit generates a bias voltage having a current value corresponding to the generated synthesized current and supplies the bias voltage to each output amplifier belonging to its own group.

### BRIEF DESCRIPTION OF THE DRAWINGS

FIG. 1 is a block diagram showing a schematic configuration of a display device 100 including a display driver according to the disclosure.

FIG. 2 is a layout diagram showing an example of an arrangement of functional blocks forming an output amplifier unit 133 according to the disclosure within a semiconductor IC chip CHP.

FIG. 3 is a block diagram showing an internal configuration of an output amplifier unit 133 according to the first embodiment.

FIG. 4 is a circuit diagram showing an internal configuration of an amplifier APx.

FIG. 5 is a circuit diagram showing internal configuration of a main bias circuit MB.

FIG. 6 is a diagram showing an example of an internal configuration of a bias control circuit BCC and an example of a circuit configuration of a sub-bias circuit SB1_R.

FIG. 7 is a time-chart showing a waveform of each of a clock signal CLK, a bias control signal PWRC, a gradation voltage Vx, and an output voltage Gx.

FIG. 8 is a diagram showing an example of a circuit configuration of a sub-bias circuit SB1_R as the second embodiment.

FIG. 9 is a block diagram showing an internal configuration of an output amplifier unit 133a according to the third embodiment.

FIG. 10 is a block diagram showing an internal configuration of an output amplifier unit 133b according to the fourth embodiment.

FIG. 11 is a block diagram showing an internal configuration of a bias control circuit BCCa.

### DESCRIPTION OF THE EMBODIMENTS

### Embodiment 1

Hereinafter, the embodiments of the disclosure will be described in detail with reference to the drawings.

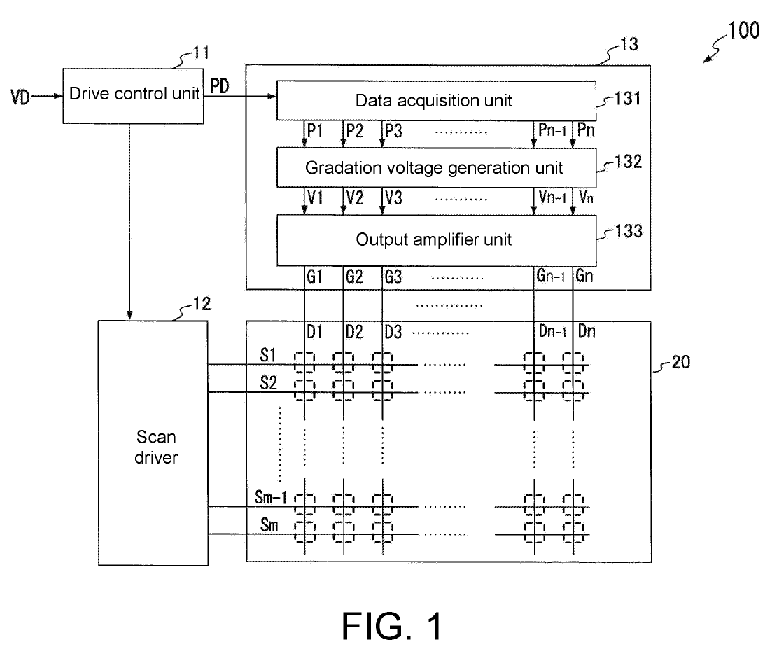

FIG. 1 is a block diagram showing a schematic configuration of a display device 100 including a display driver according to an embodiment.

As shown in FIG. 1, the display device 100 includes a drive control unit 11, a scan driver 12, a data driver 13, and a display panel 20.

The display panel 20 includes, for example, an organic EL panel or a liquid crystal display panel. In the display panel 20, scan lines S1 to Sm (m being an integer of 2 or more) extending in the horizontal direction of a two-dimensional screen and data lines D1 to Dn (n being an integer of 2 or more) extending in the vertical direction of the two-dimensional screen are formed. Display cells are formed in regions (regions surrounded by broken lines) at the respective intersections of the scan lines and data lines.

The scan lines S1 to Sm are connected to the scan driver 12, and the data lines D1 to Dn are connected to the data driver 13.

The drive control unit 11 receives a video signal VD and detects a horizontal sync signal and a vertical sync signal from the video signal VD. The drive control unit 11 supplies the detected horizontal sync signal to the scan driver 12. The drive control unit 11 also generates, based on the video signal VD, various control signals, such as a clock signal CLK synchronized with the horizontal sync signal and a load signal indicating a data acquisition timing, and a sequence of pixel data fragments representing brightness levels of respective pixels in, for example, 8-bit brightness gradation. The drive control unit 11 generates an image data signal PD including the various control signals and a row of the pixel data fragments, and supplies the image data signal PD to the data driver 13.

The scan driver 12 sequentially applies a scan pulse to each of the scan lines S1 to Sm of the display panel 20 at a timing synchronized with the horizontal sync signal supplied from the drive control unit 11.

The data driver 13 is formed on a semiconductor integrated circuit (IC) chip and includes a data acquisition unit 131, a gradation voltage generation unit 132, and an output amplifier unit 133.

The data acquisition unit 131 acquires pixel data fragments included in the image data signal PD for each scan line, that is, for every n fragments. The data acquisition unit 131 sets the acquired n pixel data fragments as pixel data P1 to Pn, and supplies the pixel data P1 to Pn to the gradation voltage generation unit 132 at the timing of, for example, a rising edge of the clock signal CLK.

The gradation voltage generation unit 132 converts the pixel data P1 to Pn supplied from the data acquisition unit 131 into gradation voltages V1 to Vn having voltage values corresponding to the brightness levels indicated by the respective pixel data. The gradation voltage generation unit 132 supplies the gradation voltages V1 to Vn to the output amplifier unit 133.

The output amplifier unit 133 supplies n voltages obtained by individually amplifying the gradation voltages V1 to Vn to data lines D1 to Dn of the display panel 20 as output voltages G1 to Gn.

Here, the data driver 13 is formed in a semiconductor IC chip having, for example, a rectangular chip shape. In the semiconductor IC chip, n output terminals for outputting the output voltages G1 to Gn to the outside are arranged in a row along one side of the rectangle, and the output amplifier unit 133 is formed near the n output terminals.

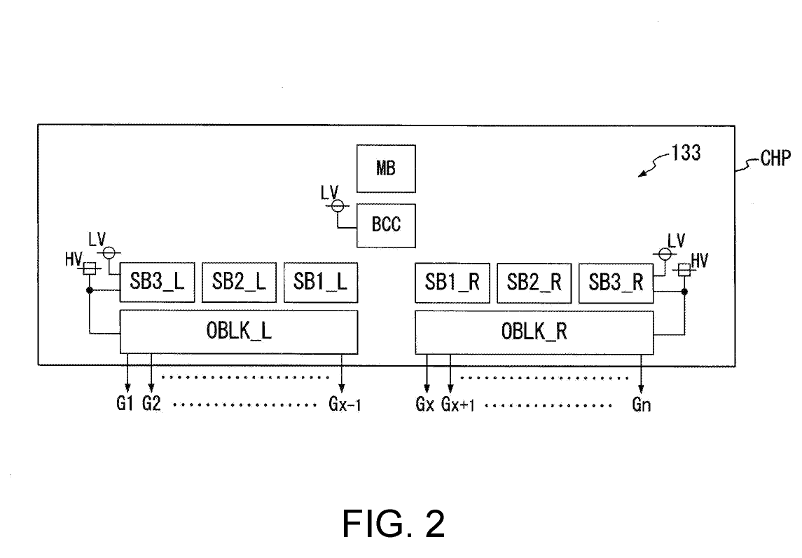

FIG. 2 is a layout diagram showing an example of an arrangement configuration of functional blocks forming the output amplifier unit 133 within the semiconductor IC chip CHP. The entire region of the semiconductor IC chip CHP is divided into a central region, a left region and a right region. The left region and the right region are adjacent on the left and right by sandwiching the central region in a direction along the long side among the four sides thereof.

As shown in FIG. 2, the output amplifier unit 133 includes, as functional blocks, a main bias circuit MB, a bias control circuit BCC, sub-bias circuits SB1_R to SB3_R, SB1_L to SB3_L, and amplifier circuits OBLK_L and OBLK_R. The main bias circuit MB and the bias control circuit BCC are disposed in the central region of the semiconductor IC chip CHP. In the left region of the semiconductor IC chip CHP, the sub-bias circuits SB1_L to SB3_L and the amplifier circuit OBLK_L responsible for generating G1 to G(x-1) (where x is an integer represented by n/2 or 1+n/2) among output voltages G1 to Gn are disposed. In the right region of the semiconductor IC chip CHP, the sub-bias circuits SB1_R to SB3_R and the amplifier circuit OBLK_R responsible for generating Gx to Gn among the output voltages G1 to Gn are arranged.

The bias control circuit BCC receives a low-power voltage LV which is a power voltage for a logic circuit, and each of the amplifier circuits OBLK_L and OBLK_R receives a high-power voltage HV for an analog circuit higher than the low-power voltage LV. Each of the sub-bias circuits SB1_L to SB3_L and SB1_R to SB3_R receives both the low-power voltage LV and the high-power voltage HV.

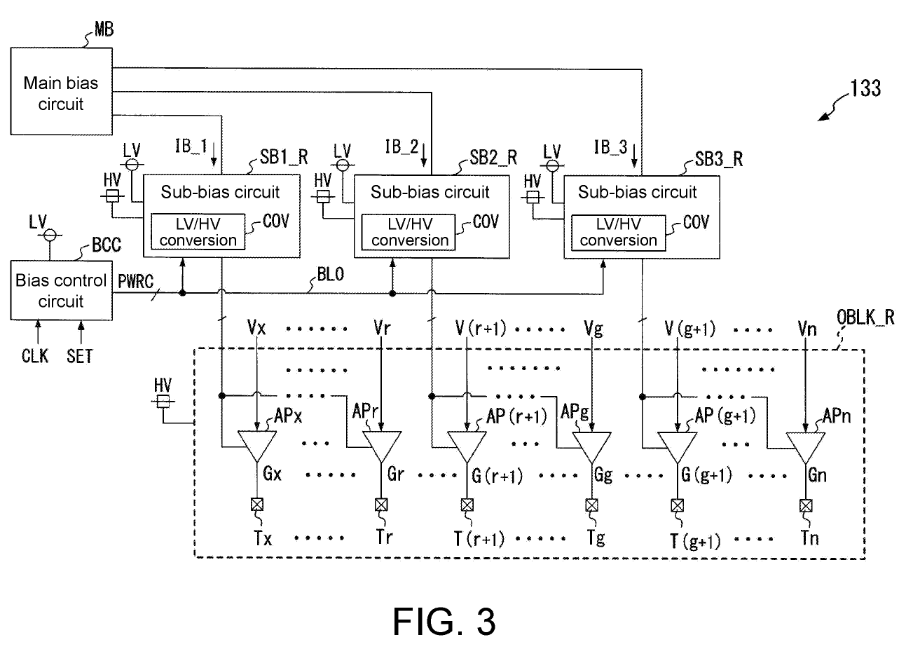

FIG. 3 is a block diagram showing a portion of the configuration of the output amplifier unit 133, that is, the main bias circuit MB, the sub-bias circuits SB1_R to SB3_R, the bias control circuit BCC, and the amplifier circuit OBLK_R from the functional block group included in the semiconductor IC chip CHP.

The output amplifier unit OBLK_R includes amplifiers APx to APn that individually receive gradation voltages Vx to Vn among the gradation voltages V1 to Vn generated by the gradation voltage generation unit 132. The amplifiers APx to APn output, as output voltages Gx to Gn, n voltages obtained by individually amplifying the respectively received gradation voltages Vx to Vn via the output terminals Tx to Tn of the semiconductor IC chip.

Each of the amplifiers APx to APn is configured by a differential amplifier including, for example, a differential stage, a current mirror stage, and an output stage. In each of the amplifiers APx to APn, the operation currents flowing through the respective differential stage and current mirror stages are set based on the bias voltage groups supplied from the sub-bias circuits SB1_R to SB3_R.

That is, in each of the amplifiers APx to APn, the output slew rate of its own is set by the bias voltage groups supplied from the sub-bias circuits SB1_R to SB3_R.

The main bias circuit MB generates three reference currents IB_1 to IB_3 each having a predetermined constant current value. The main bias circuit MB supplies the reference current IB_1 to the sub-bias circuit SB1_R, supplies the reference current IB_2 to the sub-bias circuit SB2_R, and supplies the reference current IB_3 to the sub-bias circuit SB3_R.

The bias control circuit BCC generates a bias control signal group PWRC that specifies voltage values of the bias voltage by using, for example, 3-bit bias control signals each having binary levels (LV, VSS) based on the low-power voltage LV. The bias control circuit BCC transmits such bias control signal group PWRC to each of the sub-bias circuits SB1_R to SB3_R via a wiring group BL0.

Each of the sub-bias circuits SB1_R to SB3_R is provided in correspondence with each group obtained by dividing the amplifiers APx to APn into three groups. For example, the sub-bias circuit SB1_R corresponds to a first group formed by the amplifiers AP1 to APr (r is an integer less than n). The sub-bias circuit SB2_R corresponds to a second group formed by the amplifiers AP(r+1) to APg (g is an integer greater than r and less than n). The sub-bias circuit SB3_R corresponds to a third group formed by the amplifiers AP(g+1) to APn.

The sub-bias circuit SB1_R receives the reference current IB_1 sent from the main bias circuit MB and receives the bias control signal group PWRC transmitted from the bias control circuit BCC via the wiring group BL0. The sub-bias circuit SB2_R receives the reference current IB_2 sent from the main bias circuit MB and receives the bias control signal group PWRC transmitted from the bias control circuit BCC via the wiring group BL0. The sub-bias circuit SB3_R receives the reference current IB_3 sent from the main bias circuit MB and receives the bias control signal group PWRC transmitted from the bias control circuit BCC via the wiring group BL0.

Each of the sub-bias circuits SB1_R to SB3_R has the same circuit configuration including an LV/HV conversion circuit COV as a level conversion circuit.

The LV/HV conversion circuit COV included in the sub-bias circuit SB1_R converts each signal level (LV) of the bias control signal group PWRC to a high voltage bias control signal group level-shifted to a signal level (HV) based on the high-power voltage HV higher than LV.

The sub-bias circuit SB1_R generates a bias voltage group for setting the magnitude of the operation current of each of the amplifiers APx to APr belonging to the first group based on the high-power voltage HV and the reference current IB_1. The sub-bias circuit SB1_R supplies the generated bias voltage group to each of the amplifiers APx to APr belonging to the first group.

The LV/HV conversion circuit COV included in the sub-bias circuit SB2_R converts each signal level (LV) of the bias control signal group PWRC to a high voltage bias control signal group level-shifted to a signal level (HV) based on the high-power voltage HV higher than LV.

The sub-bias circuit SB2_R generates a bias voltage group for setting the magnitude of the operation current of each of the amplifiers AP(r+1) to APg belonging to the second group based on the high-power voltage HV and the reference current IB_2. The sub-bias circuit SB2_R supplies the generated bias voltage group to each of the amplifiers AP(r+1) to APg belonging to the second group.

The LV/HV conversion circuit COV included in the sub-bias circuit SB3_R converts each signal level (LV) of the bias control signal group PWRC to a high voltage bias control signal group level-shifted to a signal level (HV) based on the high-power voltage HV higher than LV.

The sub-bias circuit SB3_R generates a bias voltage group for setting the magnitude of the operation current of each of the amplifiers AP(g+1) to APn belonging to the third group based on the high-power voltage HV and the reference current IB_3. The sub-bias circuit SB3_R supplies the generated bias voltage group to each of the amplifiers AP(g+1) to APn belonging to the third group.

In the following, the detailed configuration of the main bias circuit MB, the amplifiers APx to APn, the sub-bias circuits SB1_R to SB3_R, and the bias control circuit BCC shown in FIG. 3 will be described.

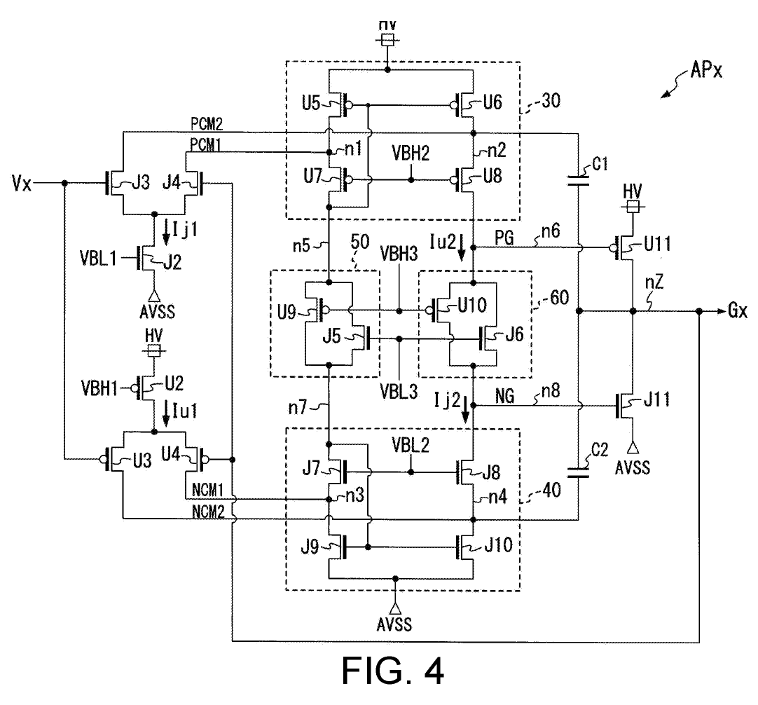

FIG. 4 is a circuit diagram showing the internal configuration by extracting the amplifier APx from the amplifiers APx to APn.

The amplifier APx includes a differential stage including P-channel type transistors U2 to U4 and N-channel type transistors J2 to J4, and an output stage including a P-channel type transistor U11 and an N-channel type transistor J11. Furthermore, the amplifier APx includes cascode current mirror circuits 30 and 40, and floating current sources 50 and 60.

The high-power voltage HV is applied to the source of the transistor U2 of the differential stage, and a bias voltage VBH1 is supplied to the gate. The transistor U2 generates the operation current Iu1 having a current value according to the bias voltage VBH1, and supplies the operation current Iu1 to the source of each of the transistors U3 and U4. The transistor U3 receives a gradation voltage Vx at the gate of its own. The transistor U4 receives the output voltage Gx, which is the output of the amplifier APx, at the gate of its own. The transistors U3 and U4 generate differential output currents as currents NCM1 and NCM2 by dividing the operation current Iu1 supplied from the transistor U2 into two according to the voltage ratio of the gradation voltage Vx and the output voltage Gx. The transistors U3 and U4 supply the currents NCM1 and NCM2 to nodes n3 and n4 of the cascode current mirror circuit 40 through the respective drains of the transistors U3 and U4. That is, the transistor U3 supplies the current NCM2 corresponding to the voltage value of the gradation voltage Vx to the node n4 of the cascode current mirror circuit 40. The transistor U4 supplies the current NCM1 corresponding to the voltage value of the output voltage Gx to the node n3 of the cascode current mirror circuit 40.

The ground voltage AVSS is applied to the source of the transistor J2 of the differential stage, and the bias voltage VBL1 is supplied to the gate. The drain of the transistor J2 is connected to the source of each of the transistors J3 and J4. The transistor J2 generates an operation current Ij1 having a current value according to the bias voltage VBL1, and extracts the operation current Ij1 from the sources of the transistors J3 and J4. The transistor J3 receives the gradation voltage Vx at the gate of its own. The transistor J4 receives the output voltage Gx at the gate of its own. The transistors J3 and J4 generate differential output currents as currents PCM1 and PCM2 by dividing the operation current Ij1 into two according to the voltage ratio of the gradation voltage Vx and the output voltage Gx received at the respective gates. The transistor J3 extracts the current PCM2 corresponding to the gradation voltage Vx from a node n2 of the cascode current mirror circuit 30, and supplies the current PCM2 to the drain of the transistor J2. The transistor J4 extracts the current PCM1 corresponding to the output voltage Gx from a node n1 of the cascode current mirror circuit 30, and supplies the current PCM1 to the drain of the transistor J2.

In the differential stage, the current value of the operation current Iu1 is adjusted by the bias voltage VBH1, and further, the current value of the operation current Ij1 is adjusted by the bias voltage VBL1. Accordingly, for example, the lower the voltage value of the bias voltage VBH1, the larger current is supplied to the nodes n3 and n4 of the cascode current mirror circuit 40. Also, the higher the voltage value of the bias voltage VBL1, the larger current is extracted from the nodes n1 and n2 of the cascode current mirror circuit 30.

The cascode current mirror circuit 30 includes P-channel type transistors U5 to U8, and the cascode current mirror circuit 40 includes N-channel type transistors J7 to J10. Also, the floating current source 50 includes a P-channel type transistor U9 and a N-channel type transistor J5, and the floating current source 60 includes a P-channel type transistor U10 and an N-channel type transistor J6.

The high-power voltage HV is applied to the source of each of the transistors U5 and U6 of the cascode current mirror circuit 30, and the respective gates thereof are connected to each other. The drain of the transistor U5 is connected to the source of the transistor U7 via the node n1. The drain of the transistor U6 is connected to the source of the transistor U8 via the node n2. A bias voltage VBH2 is applied to the gates of the transistors U7 and U8. The drain of the transistor U7 is connected, via the node n5, to the gate of each of the transistors U5 and U6, the source of the transistor U9 of the floating current source 50, and the drain of the transistor J5.

The drain of the transistor U8 is connected to the source of the transistor U10 and the drain of the transistor J6 of the floating current source 60 via the node n6 as a driving node on the high potential side. A bias voltage VBH3 is applied to the gate of each of the transistors U9 and U10, and the bias voltage VBL3 is applied to the gate of each of the transistors J5 and J6. The drain of the transistor U9 and the source of the transistor J5 are connected to the drain of the transistor J7 of the cascode current mirror circuit 40 via the node n7. The drain of the transistor U10 and the source of the transistor J6 are connected to the drain of the transistor J8 of the cascode current mirror circuit 40 via the node n8 as a driving node on the low potential side.

The bias voltage VBL2 is applied to the gate of each of the transistors J7 and J8. The source of the transistor J7 is connected to the drain of the transistor J9 via the node n3. The source of the transistor J8 is connected to the drain of the transistor J10 via node n4. The ground voltage AVSS is applied to the source of each of the transistors J9 and J10, and the gate of each of the transistors J9 and J10 is connected to the drain of the transistor J7.

In the cascode current mirror circuits 30 and 40 and the floating current sources 50 and 60, an operation current Iu2 having a current value corresponding to the difference between the current PCM1 and the current PCM2 supplied from the differential stage flows to the node n6. Furthermore, in the cascode current mirror circuits 30 and 40 and the floating current sources 50 and 60, the operation current Ij2 having a current value corresponding to the difference between the current NCM1 and the current NCM2 supplied from the differential stage flows to the node n8.

Accordingly, the cascode current mirror circuits 30 and 40 and the floating current sources 50 and 60 generate the drive voltage PG on the high potential side at the node n6 by supplying the operation current Iu2 corresponding to the difference between the currents PCM1 and PCM2 to the node n6 or extracting the operation current Iu2 from the node n6. The drive voltage PG is supplied to the gate of the transistor U11 of the output stage. Also, the cascode current mirror circuits 30 and 40 and the floating current sources 50 and 60 generate the output drive voltage NG on the low potential side at the node n8 by supplying the operation current Ij2 corresponding to the difference between the current NCM1 and the current NCM2 to the node n8 or extracting the operation current Ij2 from the node n8. The output drive voltage NG is supplied to the gate of the transistor J11 of the output stage.

The high-power voltage HV is applied to the source of the transistor U11 of the output stage. The transistor U11 generates a current corresponding to the output drive voltage PG received at the gate of its own and supplies the current to an output node nZ, thereby increasing the voltage of the output node nZ. The ground voltage AVSS is applied to the source of the transistor J11. The transistor J11 extracts a current corresponding to the output drive voltage NG received at the gate of its own from the output node nZ, thereby decreasing the voltage of the output node nZ.

Through the operation of the transistors U11 and J11, the output voltage Gx is generated at the output node nZ and is output via the output terminal. The output voltage Gx is fed back to each of the gate of the transistor U4 on the high potential side and the gate of transistor J4 on the low potential side of the differential stage.

To perform a stable output operation of the amplifier APx, the amplifier APx is provided with phase compensation capacitances C1 and C2. In FIG. 4, as an example of the connection of the phase compensation capacitances, the phase compensation capacitance C1 is connected between the output node nZ and the node n2, and the phase compensation capacitance C2 is connected between the output node nZ and the node n4.

In the configuration of the amplifier APx shown in FIG. 4, the current values of the operation currents Iu2 and Ij2 flowing to the nodes n6 and n8 as drive nodes that drive the transistors U11 and J11 of the output stage are adjusted by the bias voltages VBL1 to VBL3 and VBH1 to VBH3. Accordingly, the magnitude of the current supplied to the output node nZ and extracted from the output node nZ changes, and the driving capability of the amplifier APx is adjusted. The change speed of the output voltage Gx, that is, the slew rate, when the gradation voltage Vx of the amplifier APx changes greatly mainly depends on the operation currents Ij1 and Iu1 flowing to the differential stage. In brief, the slew rate can be regarded as the charge/discharge speed of phase compensation capacitances C1 and C2 accompanying the change of the output voltage Gx. Therefore, the larger the current values of the operation currents Ij1 and Iu1, the higher the driving capability and higher slew rate the amplifier APx can achieve.

In this way, each of the amplifiers APx to APn receives the high-power voltage HV and, as an input signal, the gradation voltage Vx as shown in FIG. 4, and generates the output voltage Gx obtained by amplifying the gradation voltage Vx by using the operation current generated based on the high-power voltage HV.

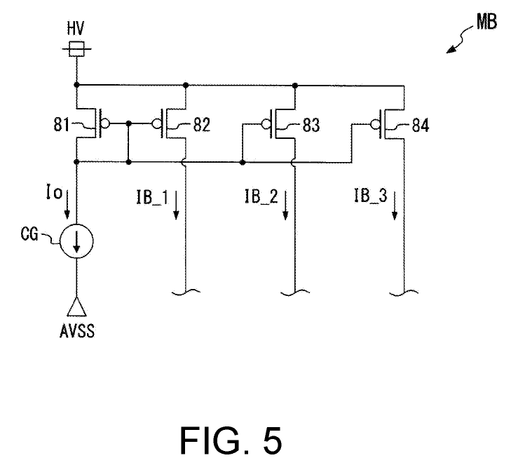

FIG. 5 is a circuit diagram showing an example of the internal configuration of the main bias circuit MB shown in FIG. 3.

As shown in FIG. 5, the main bias circuit MB includes P-channel type transistors 81 to 84 that serve as a current mirror circuit, and a current source CG.

In the transistor 81, the gate and the drain are connected to each other. The respective gates of the transistors 82 to 84 are connected to the gate of the transistor 81. The current source CG has an end connected to the drain of the transistor 81. The ground voltage AVSS is applied to the other end of the current source CG.

With such configuration, in the main bias circuit MB, a reference current Io having a predetermined constant current value generated by the current source CG flows to the drain of the transistor 81. Accordingly, the reference currents IB_1, IB_2, and IB_3 that current-mirror the reference current Io are individually supplied from the respective drains of the transistors 82 to 84 to the respective sub-bias circuits SB1_R to SB3_R.

Each of the sub-bias circuits SB1_R to SB3_R has the same internal circuit configuration as described above.

Therefore, the sub-bias circuit SB1_R is taken, among the sub-bias circuits SB1_R to SB3_R, to describe in detail the circuit configuration of the sub-bias circuit and the internal configuration of the bias control circuit BCC.

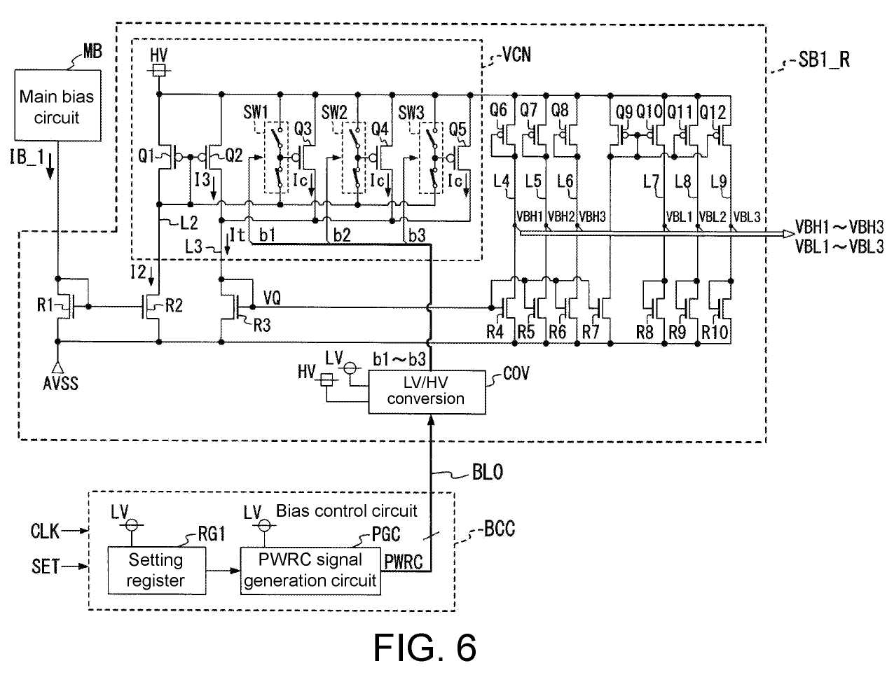

FIG. 6 is a diagram showing the internal configuration of the bias control circuit BCC and the circuit configuration of the sub-bias circuit SB1_R.

The bias control circuit BCC includes a setting register RG1 and a PWRC signal generation circuit PGC that operate by receiving the low-power voltage LV for a logic circuit.

The setting register RG1 receives a setting signal SET that includes bias voltage information specifying voltage values of the respective bias voltages VBH1 to VBH3 and VBL1 to VBL3, and switching timing information specifying the timing for switching the voltage values of the bias voltages. The setting register RG1 stores the bias voltage information and the switching timing information included in the setting signal SET, and supplies the bias voltage information and the switching timing information to the PWRC signal generation circuit PGC.

The PWRC signal generation circuit PGC generates the bias control signal group PWRC formed by 3-bit bias control signals, each having a signal level (LV, VSS) based on the low-power voltage LV, based on the clock signal CLK, the bias voltage information, and the switching timing information.

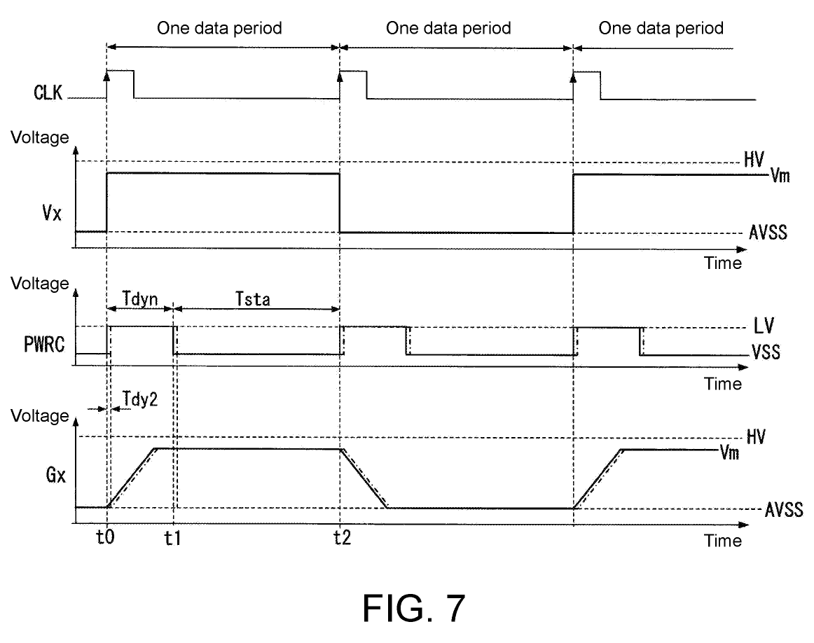

FIG. 7 is a time chart showing an example of the signal form by taking one bit of the bias control signal from the bias control signal group PWRC.

That is, as shown in FIG. 7, the PWRC signal generation circuit PGC first generates a bias control signal having the low-power voltage LV indicated by the bias voltage information at a time point t0 of, for example, the rising edge of the clock signal CLK. Subsequently, the PWRC signal generation circuit PGC switches the voltage value of the bias control signal from the low-power voltage LV to the ground voltage VSS at a time point t1 after a period Tdyn indicated by the switching timing information has elapsed from the time point t0. Here, the PWRC signal generation circuit PGC maintains the voltage value of the bias voltage control signal in the state of the ground potential VSS over a remaining period Tsta within one data period. Then, as shown in FIG. 7, the PWRC signal generation circuit PGC switches the voltage value of the bias voltage control signal from the ground voltage VSS to the low-power voltage LV at a time point t2 at the beginning of the next data period. That is, the PWRC signal generation circuit PGC generates the bias control signal group PWRC of the low-power voltage LV that increases the slew rate of the amplifier in the leading period (Tdyn) for each data period. Then, in the subsequent period (Tsta), the PWRC signal generation circuit PGC generates the bias control signal PWRC of the ground voltage VSS that decreases the slew rate of the amplifier.

As described above, the bias control circuit BCC including the setting register RG1 and the PWRC signal generation circuit PGC receives the low-power voltage LV for a logic circuit, which is lower than the high-power voltage HV, as the power voltage for operating itself. Then, the bias control circuit BCC generates the bias control signal group PWRC that specifies the voltage value of the bias voltage with 3 bits at a signal level (LV, VSS) based on the low-power voltage LV, and transmits the bias control signal group PWRC to each of the sub-bias circuits SB1_R to SB3_R via the wiring group BL0.

As shown in FIG. 6, the sub-bias circuit SB1_R includes the LV/HV conversion circuit COV and an adjustment circuit VCN including P-channel MOS type transistors Q1 to Q5 and switch circuits SW1 to SW3. Furthermore, the sub-bias circuit SB1_R includes P-channel MOS type transistors Q6 to Q12, and N-channel MOS type transistors R1 to R10.

As described above, the LV/HV conversion circuit COV level-shifts each signal level of the bias control signal group PWRC from a signal level (LV, VSS) based on the low-power voltage LV to a signal level (HV, AVSS) based on the high-power voltage HV. The LV/HV conversion circuit COV acquires three bias control signals, each having a signal level (HV, AVSS) based on the high-power voltage HV and converted by such level shift, as high voltage bias control signals b1 to b3, and supplies each of the high voltage bias control signals b1 to b3 to the adjustment circuit VCN.

The transistor R1 receives the reference current IB_1 supplied from the main bias circuit MB at the drain of its own. The drain and the gate of the transistor R1 are connected to the gate of the transistor R2, and the ground voltage AVSS is applied to the source of each of the transistors R1 and R2. The drain of the transistor R2 is connected to the adjustment circuit VCN via a node L2.

With such configuration, the transistor R2 generates a current I2 corresponding to the reference current IB_1 and flows the current I2 to the node L2.

The gate of each of the transistors Q1 and Q2 of the adjustment circuit VCN is connected to the node L2. The high-power voltage HV is applied to the source of each of the transistors Q1 and Q2. The drain of the transistor Q2 is connected to the drain and the gate of the transistor R3 via a node L3. The ground voltage AVSS is applied to the source of the transistor R3. With such configuration, the transistor Q2 generates a reference bias voltage VQ at the node L3 by sending a current I3 corresponding to the current I2 to the node L3. The high-power voltage HV is applied to the source of each of the transistors Q3 to Q5 of the adjustment circuit VCN, and the respective drains thereof are connected to the node L3.

The switch circuit SW1 receives a high voltage bias control signal b1 sent from the LV/HV conversion circuit COV. The switch circuit SW1 is set to a state in which the high-power voltage HV is supplied to the gate of the transistor Q3 (referred to as OFF state) or a state in which the node L2 is connected to the gate of the transistor Q3 (referred to as ON state) according to the high voltage bias control signal b1. The switch circuit SW2 receives the high voltage bias control signal b2 sent from the LV/HV conversion circuit COV. The switch circuit SW2 is set to a state in which the high-power voltage HV is supplied to the gate of the transistor Q4 (referred to as OFF state) or a state in which the node L2 is connected to the gate of the transistor Q4 (referred to as ON state) according to the high voltage bias control signal b2. The switch circuit SW3 receives a high voltage bias control signal b3 sent from the LV/HV conversion circuit COV. The switch circuit SW3 is set to a state in which the high-power voltage HV is supplied to the gate of the transistor Q5 (referred to as OFF state) or a state in which the node L2 is connected to the gate of the transistor Q5 (referred to as ON state) according to the high voltage bias control signal b3.

The transistor Q3 becomes the ON state only in the case where the switch circuit SW1 becomes the ON state, and sends a current Ic, which current-mirrors the current I2, to the node L3. The transistor Q4 becomes the ON state only in the case where the switch circuit SW2 becomes the ON state, and sends the current Ic, which current-mirrors the current I2, to the node L3. The transistor Q5 becomes the ON state only in the case where the switch circuit SW3 becomes the ON state, and sends the current Ic, which current-mirrors the current I2, to the node L3.

With the configuration, the adjustment circuit VCN sends a combined current, which combines the current I3 corresponding to the reference current IB_1 and the current Ic sent from each of the transistors Q3 to Q5, to the node L3 as the adjustment current It.

For example, in the case where the adjustment circuit VCN receives the high voltage bias control signals b1 to b3 respectively having the signal level of the high-power voltage HV, the transistors Q3 to Q5 all become the OFF state. As a result, the adjustment current It flowing to the node L3 becomes only the current I3 sent from the transistor Q2. Also, for example, in the case where the adjustment circuit VCN receives the high voltage bias control signals b1 to b3 respectively having the signal level of the ground voltage AVSS, the transistors Q3 to Q5 all become the ON state. As a result, the adjustment current It flowing to the node L3 becomes a current (I3+3·Ic) obtained by adding the current Ic sent from each of the transistors Q3 to Q5 to the current I3 sent from the transistor Q2. Also, for example, in the case where the adjustment circuit VCN receives the high voltage bias control signal b1 having a signal level of the ground voltage AVSS and the high voltage bias control signals b2 and b3 both having a signal level of the high-power voltage HV, only Q3 among transistors Q3 to Q5 becomes the ON state. As a result, the adjustment current It flowing to the node L3 becomes the current (I3+Ic) obtained by adding the current Ic sent from the transistor Q3 to the current I3 sent from the transistor Q2.

In this way, the adjustment circuit VCN generates, as the adjustment current It, a current obtained by current-mirroring the reference current (IB_1, I2) at a current mirror ratio based on the high voltage bias control signal.

And, by sending the adjustment current It generated to the node L3, a voltage having a voltage value corresponding to the magnitude of the adjustment current It is generated at the node L3 as the reference bias voltage VQ.

Here, as shown in FIG. 6, the gate of each of the transistors R4 to R7 is connected to the gate of the transistor R3 and the node L3, and the ground voltage AVSS is applied to the source of each of the transistors R4 to R7.

The drain of the transistor R4 is connected to the gate and the drain of the transistor Q6 via a node L4. The drain of the transistor R5 is connected to the gate and the drain of the transistor Q7 via a node L5. The drain of the transistor R6 is connected to the gate and the drain of the transistor Q8 via a node L6. The high-power voltage HV is applied to the source of each of the transistors Q6 to Q8.

The drain of the transistor R7 is connected to the drain of the transistor Q9 and the gate of each of the transistors Q9 to Q12. The high-power voltage HV is applied to the source of each of the transistors Q9 to Q12. The drain of the transistor Q10 is connected to the gate and the drain of the transistor R8 via a node L7. The drain of the transistor Q11 is connected to the gate and the drain of the transistor R9 via a node L8. The drain of the transistor Q12 is connected to the gate and the drain of the transistor R9 via a node L9. The ground voltage AVSS is applied to the source of each of the transistors R8 to R10.

In a circuit including the transistors R4 and Q6, the transistor R4 flows a current corresponding to the reference bias voltage VQ supplied to the gate of its own to the node L4. Accordingly, the voltage generated at the node L4 is supplied to the amplifiers APx to APn as the bias voltage VBH1. In a circuit including the transistors R5 and Q7, transistor R5 flows a current corresponding to the reference bias voltage VQ and supplied to the gate of its own to the node L5. Accordingly, the voltage generated at the node L5 is supplied to the amplifiers APx to APn as the bias voltage VBH2. In the circuit including the transistors R6 and Q8, the transistor R6 flows a current corresponding to the reference bias voltage VQ supplied to the gate of its own to the node L6. Accordingly, the voltage generated at the node L6 is supplied to the amplifiers APx to APn as the bias voltage VBH3.

The transistor R7 flows a current corresponding to the reference bias voltage VQ supplied to the gate of its own through the transistor Q9. Accordingly, a current corresponding to the reference bias voltage VQ is sent from the drain of each of the transistors Q10 to Q12 to the nodes L7 to L9, respectively. At this time, the voltage generated at the node L7 by the transistor Q10 sending a current corresponding to the reference bias voltage VQ to the node L7 is supplied to the amplifiers APx to APn as the bias voltage VBL1. Also, the voltage generated at the node L8 by the transistor Q11 sending a current corresponding to the reference bias voltage VQ to the node L8 is supplied to the amplifiers APx to APn as the bias voltage VBL2. Also, the voltage generated at the node L9 by the transistor Q12 sending a current corresponding to the reference bias voltage VQ to the node L9 is supplied to the amplifiers APx to APn as the bias voltage VBL3.

In this way, in the sub-bias circuit SB1_R, the bias voltages VBH1 to VBH3 and VBL1 to VBL3 are generated by performing a current-voltage conversion process on the reference current IB_1 by using a current-voltage conversion circuit including the transistors R3 to R10 and Q6 to Q12.

The sub-bias circuit SB1_R switches the voltage value of each of the bias voltages VBH1 to VBH3 and VBL1 to VBL3 in two stages for each data period according to the bias control signal group PWRC shown in FIG. 7.

That is, as shown in FIG. 7, the bias control signal group PWRC maintains a state of the low-power voltage LV that instructs a high slew rate of the amplifier in the leading period Tdyn for each data period, and maintains a state of the ground voltage VSS that instructs a low slew rate in the subsequent period Tsta.

In response to such bias control signal group PWRC, the sub-bias circuit SB1_R generates bias voltages (VBH1 to VBH3, VBL1 to VBL3) having first voltage values leading to a high slew rate of the amplifiers APx to APn in the period Tdyn shown in FIG. 7. Then, in the period Tsta subsequent to the period Tdyn, the sub-bias circuit SB1_R generates bias voltages (VBH1 to VBH3, VBL1 to VBL3) having second voltage values that lead to a low slew rate of the amplifiers APx to APn. The bias voltages (first voltage values) in the period Tdyn are variably set by through combination of logic values (LV/VSS) of the 3-bit bias control signals that generate the PWRC signals in the period Tdyn, and the adjustment to the level that leads to a high slew rate in the period Tdyn can be made.

According to the operation, within each data period, in the leading period Tdyn, the operation current flowing in each of the amplifiers APx to APn becomes larger than that in the subsequent period Tsta. As a result, at the beginning of one data period, for example, the slew rate of the amplifier APx increases, and as shown in FIG. 7, even in the case where the gradation voltage Vx having a large voltage value (Vm) is input, the rise time or the fall time of the output voltage Gx can be shortened. On the other hand, in the period Tsta subsequent to the leading period Tdyn, since the voltage change of the output voltage Gx is sufficiently small, there is no need to increase the slew rate, so the operation current flowing in the amplifier APx is reduced to lower the power consumption. That is, according to the sub-bias circuit SB1_R, it is possible to perform high-speed response processing with low power consumption.

By adopting the configuration shown in FIG. 6 in the sub-bias circuits SB2_R and SB3_R as well, it becomes possible to achieve high-speed response processing with low power consumption.

In output amplifier unit 133 of the disclosure, as shown in FIG. 2, within a semiconductor IC chip, the distances from the position of the bias control circuit BCC to the respective sub-bias circuits SB1_R, SB2_R, and SB3_R (SB1_L, SB2_L, SB3_L) are different.

Therefore, the wiring lengths of the wiring group BL0 that transmits the bias control signal group PWRC generated by the bias control circuit BCC to the respective sub-bias circuits also differ between, for example, the sub-bias circuits SB1_R and SB3_R. As a result, for example, as shown in FIG. 7, the delay time from the bias control circuit BCC sending out the bias control signal group PWRC until reaching the sub-bias circuit SB3_R becomes longer than the delay time until reaching the sub-bias circuit SB1_R. At this time, when the difference in the delay times is large, for example, the amplifier APn that receives the bias voltage group from the sub-bias circuit SB3_R and the amplifier APr that receives the bias voltage group from sub-bias circuit SB1_R have a difference in the rise (fall) time of the output voltage output from each. As a result, there is a risk of causing display unevenness.

Therefore, in the output amplifier unit 133 of the disclosure, the bias control signal group PWRC is transmitted to the respective sub-bias circuits (SB1_R to SB3_R, SB1_L to SB3_L) in the form of a low signal level based on the low-power voltage LV lower than the high-power voltage HV that operates the amplifiers AP1 to APn. By transmitting with the low-amplitude voltage signals based on the low-power voltage LV in this way, the signal waveform distortion or delay during low level/high level switching can be reduced when compared to high-amplitude voltage signal transmission based on the high-power voltage HV. At this time, in the output amplifier unit 133 of the disclosure, within each sub-bias circuit, by converting each signal level of the bias control signal group PWRC to the high signal level based on the high-power voltage HV, the control of the slew rate of the amplifiers operating at the high-power voltage HV is achieved.

Therefore, according to the output amplifier unit 133 of the disclosure, it becomes possible to suppress the degradation of signal waveforms of the wiring group BL0 used for such transmission, as compared to the case where the bias control signal group is transmitted to each sub-bias circuit in the form of the high signal level based on the high-power voltage HV. Also, it becomes possible to reduce the sizes of the elements, such as the output transistor and other elements that handle the output of the bias control signal group PWRC within the bias control circuit BCC configured by using low-voltage transistors having a high current driving capability.

In this way, the binary bias control signal group PWRC based on the low-power voltage LV has a smaller signal amplitude than binary signals based on the high-power voltage HV. Therefore, the rise time or fall time becomes shorter correspondingly. That is, according to the output amplifier unit 133 of the disclosure, the transmission delay time of the bias control signal group PWRC can be shortened.

As a result, it becomes possible to reduce the time difference between the delay time from the bias control circuit BCC sending out the bias control signal group PWRC until reaching the sub-bias circuit SB3_R and the delay time until the reaching sub-bias circuit SB1_R.

Therefore, the difference between the rise (fall) time of the output voltage of the amplifier group that receives the bias voltage from the sub-bias circuit SB3_R and the rise (fall) time of the output voltage of the amplifier group that receives the bias voltage from the sub-bias circuit SB1_R becomes smaller. Accordingly, it is possible to suppress the display unevenness associated with the time difference.

As described in detail above, according to the output amplifier unit 133 of the disclosure, it becomes possible to suppress the display unevenness, achieve high-speed response, and reduce power consumption.

In the embodiment, the sub-bias circuits SB1_R to SB3_R and SB1_L to SB3_L of six systems are adopted as the sub-bias circuits included in output amplifier unit 133, but the number of the sub-bias circuits is not limited to six. Also, the circuit configuration of the sub-bias circuits is not limited to that shown in FIG. 6, and the circuit configuration of each amplifier is not limited to that shown in FIG. 4.

In brief, it suffices as long as the output amplifier unit 133 includes multiple amplifiers as follows, 1^{st} to K^{th} (K being an integer of 2 or more) sub-bias circuits, and a bias control circuit.

That is, each of the amplifiers (e.g., APx to APn) receives a predetermined high-power voltage (HV) and an input signal (e.g., Vx), and generates an output voltage (e.g., Gx) by amplifying the input signal by using an operation current generated based on the high-power voltage. The 1^{st} to K^{th} sub-bias circuits (e.g., SB1_R to SB3_R) are provided in correspondence with the respective 1^{st} to K^{th} amplifier groups obtained by dividing the amplifiers into predetermined quantities. Each of the 1^{st} to K^{th} sub-bias circuits generates a bias voltage (e.g., VBH1 to VBH3, VBL1 to VBL3) for setting the magnitude of the operation current of the amplifier based on the high-power voltage and the reference current, and supplies the bias voltage to each amplifier belonging to each corresponding one of the 1^{st} to K^{th} amplifier groups. A bias control circuit (BCC) receives the low-power voltage (LV) lower than the high-power voltage (HV), and generates the bias control signal (PWRC) indicating the voltage value of bias voltage at a signal level based on the low-power voltage. The bias control circuit transmits the generated bias control signal to each of the 1^{st} to K^{th} sub-bias circuits via a wiring (BL0). Each of the 1^{st} to K^{th} sub-bias circuits includes a level conversion circuit (COV) that obtains a high voltage bias control signal (e.g., b1 to b3) in which the signal level of the received bias control signal (PWRC) is switched from a signal level based on the low-power voltage (LV) to a signal level based on the high-power voltage (HV). Each of the 1^{st} to K^{th} sub-bias circuits generates a bias voltage having a voltage value based on the high voltage bias control signal.

### Embodiment 2

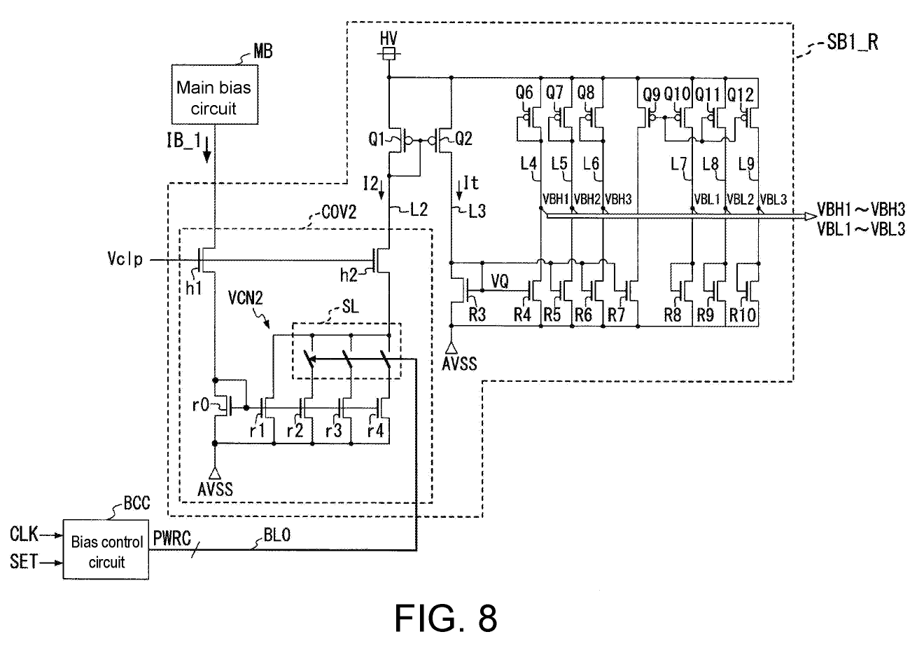

FIG. 8 is a circuit diagram showing another circuit configuration of the sub-bias circuit SB1_R obtained by extracting the sub-bias circuit SB1_R from the sub-bias circuits SB1_R to SB3_R.

The main bias circuit MB and the bias control circuit BCC shown in FIG. 8 are the same as those shown in FIG. 6.

The sub-bias circuit SB1_R shown in FIG. 8 is obtained by incorporating the voltage adjustment function performed by the adjustment circuit VCN shown in FIG. 6 into the LV/HV conversion circuit COV.

That is, the sub-bias circuit SB1_R shown in FIG. 8 is obtained by removing transistors R1 and R2 and the transistors Q3 to Q5 and the switch circuits SW1 to SW3 included in the adjustment circuit VCN from the configuration shown in FIG. 6. However, in the sub-bias circuit SB1_R shown in FIG. 8, a LV/HV conversion circuit COV2 is adopted as the level conversion circuit instead of the LV/HV conversion circuit COV shown in FIG. 6, and other circuit configurations are the same as those shown in FIG. 6.

The LV/HV conversion circuit COV2 includes N-channel type transistors h1 and h2 as a level conversion circuit that carries LV/HV conversion, and a selector SL and N-channel type transistors r0 to r4 as an adjustment circuit VCN2.

The transistor h1 serving as the level conversion circuit receives a predetermined clamp voltage Vc1p at the gate, receives the reference current IB_1 based on the high-power voltage HV sent from the main bias circuit MB at the drain, and performs conversion into a current based on the low-power voltage LV. The transistor h2 receives the clamp voltage Vc1p at the gate and converts the adjustment current based on the low-power voltage LV generated by the adjustment circuit VCN2 to an adjustment current I2 based on the high-power voltage HV, outputs the adjustment current I2 from the drain as a sink current, and supplies the adjustment current I2 to the transistor Q1. The clamp voltage Vc1p has the same voltage value as the low-power voltage LV that is, for example, a power voltage for a logic circuit. Also, the transistors h1 and h2 only bridge the current between the LV circuit and the HV circuit configured with an element breakdown voltage according to the power voltage, and do not affect the current value. The transistors h1 and h2 are configured with high breakdown voltage transistors corresponding to the high-power voltage HV.

The transistor r0 serving as the adjustment circuit VCN2 has the gate and the drain thereof connected to each other, and the ground voltage AVSS is applied to the source. Transistors r1 to r4 serving as the adjustment circuit VCN2 have the respective gates commonly connected to the gate of the transistor r0, and the ground voltage AVSS is commonly applied to the respective sources. The drain of the transistor r1 is connected to the source of the transistor h2, and the drains of the transistors r2 to r4 are each connected to the selector SL. That is, the transistors r0 to r4 serve as a current mirror that current-mirrors the reference current received via the transistor h1 to generate four currents.

The selector SL includes the first to third switches that individually become the ON state or the OFF state according to the bias control signal group PWRC. One end of each of the first to third switches is commonly connected to the source of the transistor h2, and the other ends of the first to third switches are individually connected to the drains of the transistors r2 to r4, respectively. The selector SL receives the bias control signal group PWRC based on the low-power voltage LV transmitted from the bias control circuit BCC via the wiring group BL0. The selector SL adjusts the magnitude of the current (sink current) flowing to the source of the transistor h2 by turning a number of switches among the first to third switches to the ON state based on the bias control signal group PWRC.

In FIG. 8, the main bias circuit MB may be configured as a circuit that operates by receiving the low-power voltage LV and generates the reference current IB_1 based on the low-power voltage LV. In such case, the low-power voltage LV is used not only for the logic circuit but also for the analog circuit, and the N-channel type transistor h1 that handles LV/HV conversion of the LV/HV conversion circuit COV2 becomes unnecessary.

That is, the LV/HV conversion circuit COV2 includes the adjustment circuit VCN2 and a level conversion unit. The adjustment circuit VCN2 generates an adjustment current based on the low-power voltage having a magnitude obtained by current-mirroring the reference current with a current mirror ratio based on the bias control signal PWRC. The level conversion unit includes at least the transistor h2 that receives the predetermined clamp voltage Vclp at the gate, and transistor h2 converts the adjustment current based on the low-power voltage to the adjustment current (I2) based on the high-power voltage and outputs to the adjustment current as a sink current from the drain. At this time, in the LV/HV conversion circuit COV2, LV/HV conversion is performed by the transistor h2 to convert the current adjusted according to the bias control signal PWRC based the on low-power voltage LV to the adjustment current (I2) based on the high-power voltage HV.

Here, in the sub-bias circuit SB1_R, the adjustment current It which is based on the high-power voltage HV, current-mirrored from the adjustment current (I2) by a current mirror formed by the transistors Q1 and Q2, is sent out. Then, the bias voltage group (VBH1 to VBH3, VBL1 to VBL3) based on the adjustment current It is generated by a current-voltage conversion circuit formed by the transistors R3 to R10 and Q6 to Q12.

By the way, the LV/HV conversion circuit COV2 adopts the adjustment circuit VCN2 that operates with the low-power voltage LV as shown in FIG. 8. Therefore, according to the circuit configuration of the sub-bias circuit SB1_R shown in FIG. 8, it becomes possible to reduce the area as compared to the case where the bias adjustment circuit (SW1 to SW3, Q3 to Q5) that operates with high-power voltage HV is used as shown in FIG. 6.

Thus, each of the sub-bias circuits SB1_R to SB3_R shown in FIG. 8 includes the level conversion circuit and current-voltage conversion circuit as follows.

That is, the level conversion circuit (COV2) includes the following adjustment circuit and the level conversion unit. The adjustment circuit (VCN2) generates, as the first adjustment current based on the low-power voltage, a current obtained by current-mirroring a reference current (e.g., IB_1) with a current mirror ratio based on the bias control signal (PWRC). The level conversion unit includes the transistor (h2) that receives the predetermined clamp voltage (Vclp) at the gate, converts the first adjustment current based on the low-power voltage to the second adjustment current (I2) based on the high-power voltage, and outputs to the second adjustment current (I2) from the drain. The current-voltage conversion circuit (R3 to R10, Q6 to Q12) generates a voltage corresponding to the magnitude of the second adjustment current as bias voltage (VBH1 to VBH3, VBL1 to VBL

### Embodiment 3

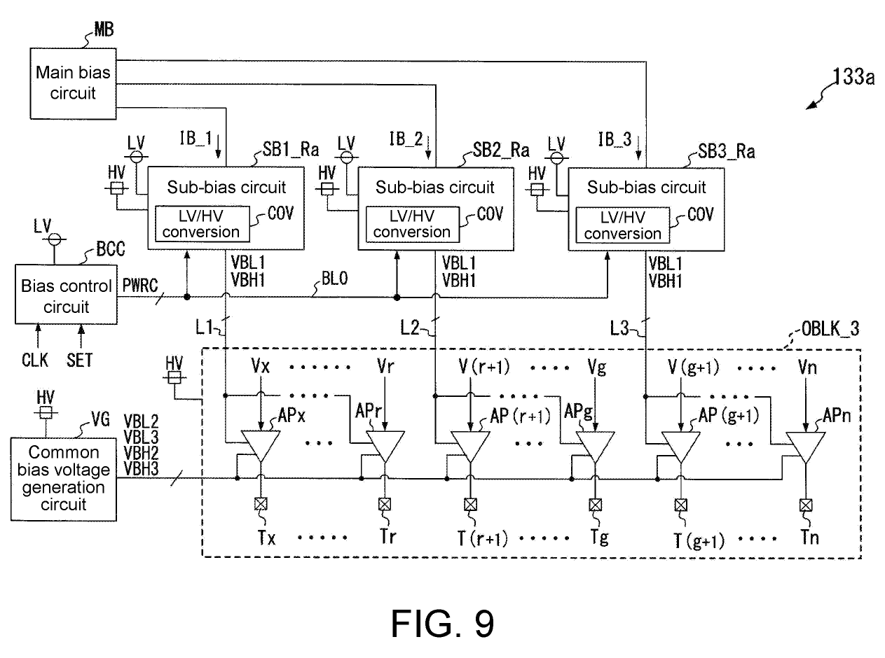

FIG. 9 is a block diagram showing a configuration of an output amplifier unit 133a as a third embodiment.

The output amplifier unit 133a adopts sub-bias circuits SB1_Ra to SB3_Ra in place of the sub-bias circuits SB1_R to SB3_R and newly provides a common bias voltage generation circuit VG, and other configurations are the same as those shown in FIG. 3.

The common bias voltage generation circuit VG generates the bias voltages VBH2, VBH3, VBL2, and VBL3 with fixed voltage values as other bias voltages excluding the bias voltages VBH1 and VBL1, and supplies the bias voltages VBH2, VBH3, VBL2, and VBL3 to the of amplifiers APx to APn, respectively.

That is, in the output amplifier unit 133a, among the bias voltage groups supplied to each of amplifiers APx to APn, only the bias voltages VBH1 and VBL1 that control tail current of differential pairs directly connected to driving capability, for example, are generated by the sub-bias circuits SB1_Ra to SB3_Ra, respectively.

Therefore, in each of the sub-bias circuits SB1_Ra to SB3_Ra, it becomes unnecessary to generate the bias voltages VBL2, VBL3, VBH2, and VBH3. That is, in each of the sub-bias circuits SB1_Ra to SB3_Ra, the transistors Q7, Q8, Q11, Q12, R5, R6, R9, and R10 shown in FIG. 6 or FIG. 8 become unnecessary. Therefore, according to the output amplifier unit 133a, it becomes possible to reduce the area as compared to the case of adopting the circuit shown in FIG. 6 or FIG. 8 as each sub-bias circuit.

### Embodiment 4

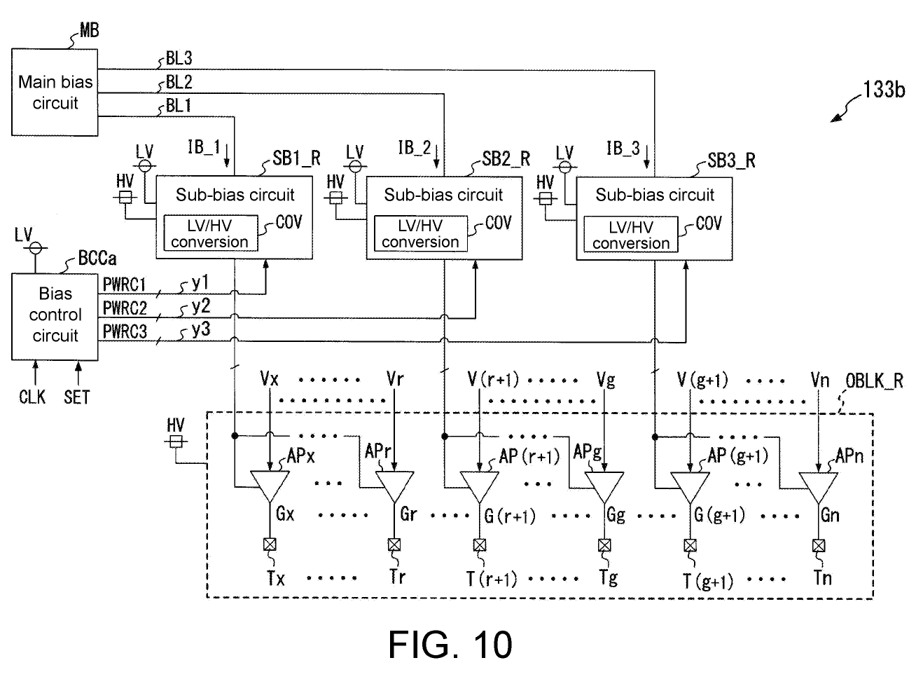

FIG. 10 is a block diagram showing a configuration of an output amplifier unit 133b as a fourth embodiment.

The output amplifier unit 133b has the same configuration as that shown in FIG. 6 except that a bias control circuit BCCa is employed in place of the bias control circuit BCC.

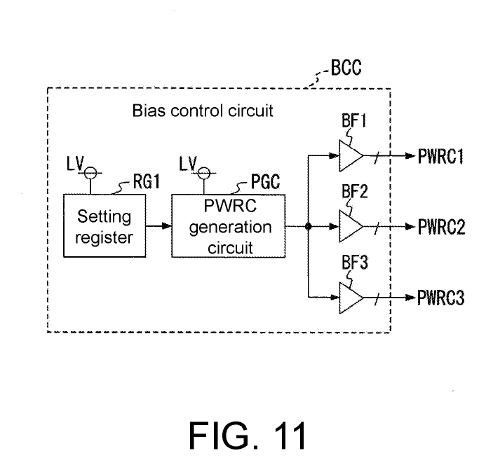

FIG. 11 is a block diagram showing an example of the internal configuration of the bias control circuit BCCa.

As shown in FIG. 11, the bias control circuit BCCa includes the setting register RG1 and the PWRC signal generation circuit PGC, similar to bias control circuit BCCa shown in FIG. 6. Furthermore, the bias control circuit BCCa includes output buffers BF1 to BF3.

The output buffer BF1 supplies a signal obtained by amplifying the bias control signal group PWRC output from the PWRC signal generation circuit PGC to the sub-bias circuit SB1_R via a wiring group y1 as the bias control signal group PWRC1. The output buffer BF2 supplies a signal obtained by amplifying the bias control signal group PWRC to the sub-bias circuit SB2_R via a wiring group y2 as a bias control signal group PWRC2. The output buffer BF3 supplies a signal obtained by amplifying the bias control signal group PWRC to sub-bias circuit SB3_R via wiring group y3 as a bias control signal group PWRC3. Each of the wiring groups y1 to y3 is configured by independent wiring not in electrical contact with each other.

Accordingly, as shown in FIG. 3, compared to the case where the bias control signal group PWRC is transmitted to each of the sub-bias circuits SB1_R to SB3_R via the common wiring group BL0, it becomes possible to suppress the variation in the timing at which the bias control signal group reaches each sub-bias circuit.

The disclosure is not limited to the forms of Embodiments 1 to 4, and various improvements and design changes are possible within a scope that does not depart from the gist of the disclosure.

### Appendix

The following configurations are disclosed in the specification.

### Configuration 1

An output amplifier circuit includes: multiple amplifiers, each receiving a predetermined high-power voltage and an input signal and generating an output voltage obtained by amplifying the input signal by using an operation current generated based on the high-power voltage; 1^{st} to K^{th} sub-bias circuits, provided respectively in correspondence with 1^{st} to K^{th} amplifier groups, K being an integer of 2 or more, obtained by dividing the amplifiers respectively into a predetermined quantity, generating bias voltages for setting magnitudes of the operation currents based on the high-power voltage, and supplying the bias voltage to each amplifier belonging to each corresponding one of the 1^{st} to K^{th} amplifier groups; and a bias control circuit, generating a bias control signal indicating a voltage value of the bias voltage at a signal level based on a low-power voltage lower than the high-power voltage, and transmitting, via a wiring, the bias control signal to each of the 1^{st} to K^{th} sub-bias circuits. Each of the 1^{st} to K^{th} sub-bias circuits includes: a level conversion circuit, obtaining a high voltage bias control signal converting the signal level of the bias control signal received by itself from the signal level based on the low-power voltage into the signal level based on the high-power voltage, and generates the bias voltage having a voltage value based on the high voltage bias control signal.

### Configuration 2

The output amplifier circuit according to Configuration 1 includes: a common bias voltage generation circuit, generating the common bias voltage in which a voltage value is fixed and supplying the common bias voltage to each of the amplifiers. In each of the amplifiers, the operation current is set according to the bias voltage and the common bias voltage.

Configuration 3

In the output amplifier circuit according to Configuration 1 or 2, the bias control circuit individually transmits the bias control signal to the 1^{st} to K^{th} sub-bias circuits via 1^{st} to K^{th} wirings not in electrical contact with each other.

### Configuration 4

In the output amplifier circuit according to any one of Configurations 1 to 3, the amplifiers, the main bias circuit, the 1^{st} to K^{th} sub-bias circuits and the bias control circuit are formed on a single semiconductor IC chip, the 1^{st} to K^{th} sub-bias circuits are arranged in a row along a side of the semiconductor IC chip, and the main bias circuit and the bias control circuit are disposed at a central portion of the semiconductor IC chip.

### Configuration 5

A display driver, has: a gradation voltage generation circuit, generating multiple gradation voltages respectively having voltage values corresponding to brightness levels of respective pixels based on a video signal; and an output unit, including the output amplifier circuit according to any one of Configurations 1 to 4, and supplying the output voltages obtained by individually amplifying, as the input signals, the respective gradation voltages by using the amplifiers of the output amplifier circuit to multiple data lines of a display panel.

### Configuration 6

An output amplifier circuit includes: multiple amplifiers, each receiving a predetermined high-power voltage and an input signal and generating an output voltage obtained by amplifying the input signal by using an operation current generated based on the high-power voltage; a main bias circuit, generating a reference current having a predetermined constant current value; 1^{st} to K^{th} sub-bias circuits, provided respectively in correspondence with 1^{st} to K^{th} amplifier groups, K being an integer of 2 or more, obtained by dividing the amplifiers respectively into a predetermined quantity, generating bias voltages for setting magnitudes of the operation currents based on the high-power voltage, and supplying the bias voltage that is generated to each amplifier belonging to each of the 1^{st} to K^{th} amplifier groups; and a bias control circuit, receiving a low-power voltage lower than the high-power voltage, generating a bias control signal indicating a voltage value of the bias voltage at a signal level based on the low-power voltage, and transmitting, via a wiring, the bias control signal that is generated to each of the 1^{st} to K^{th} sub-bias circuits. Each of the 1^{st} to K^{th} sub-bias circuits includes: a level conversion circuit, having: an adjustment circuit, generating, as a first adjustment current, based on the low-power voltage, a current having a magnitude obtained by current-mirroring the reference current at a current mirror ratio based on the bias control signal; and a level conversion circuit including: a transistor that receives a predetermined clamp voltage at a gate of the transistor and converts the first adjustment current into a second adjustment current based on the high-power voltage; and a current-voltage conversion circuit, generating, as the bias voltage, a voltage corresponding to a magnitude of the second adjustment current.

### Configuration 7

The output amplifier circuit according to Configuration 6 includes: a common bias voltage generation circuit, generating the common bias voltage in which a voltage value is fixed and supplying the common bias voltage to each of the amplifiers. In each of the amplifiers, the operation current is set by receiving the bias voltage and the common bias voltage.

### Configuration 8

In the output amplifier circuit according to Configuration 6 or 7, the bias control circuit individually transmits the bias control signal to the 1^{st} to K^{th} sub-bias circuits via 1^{st} to K^{th} wirings not in electrical contact with each other.

### Configuration 9

In the output amplifier circuit according to any one of Configurations 6 to 8, the amplifiers, the main bias circuit, the 1^{st} to K^{th} sub-bias circuits and the bias control circuit are formed on a single semiconductor IC chip. The 1^{st} to K^{th} sub-bias circuits are arranged in a row along a side of the semiconductor IC chip, and the main bias circuit and the bias control circuit are disposed at a central portion of the semiconductor IC chip.

### Configuration 10

A display driver has: a gradation voltage generation circuit, generating multiple gradation voltages respectively having voltage values corresponding to brightness levels of respective pixels based on a video signal; and an output unit, including the output amplifier circuit according to any one of Configurations 6 to 9, and supplying the output voltages obtained by individually amplifying, as the input signals, the respective gradation voltages by using the amplifiers of the output amplifier circuit to multiple data lines of a display panel.

What is claimed is:

1. An output amplifier circuit, comprising:
a plurality of amplifiers, each receiving a predetermined high-power voltage and an input signal and generating an output voltage obtained by amplifying the input signal by using an operation current generated based on the high-power voltage;
1^{st} to K^{th} sub-bias circuits, provided respectively in correspondence with 1^{st} to K^{th} amplifier groups, K being an integer of 2 or more, obtained by dividing the amplifiers respectively into a predetermined quantity, generating bias voltages for setting magnitudes of the operation currents based on the high-power voltage, and supplying the bias voltage to each amplifier belonging to each corresponding one of the 1^{st} to K^{th} amplifier groups; and
a bias control circuit, generating a bias control signal indicating a voltage value of the bias voltage at a signal level based on a low-power voltage lower than the high-power voltage, and transmitting, via a wiring, the bias control signal to each of the 1^{st} to K^{th} sub-bias circuits,
wherein each of the 1^{st} to K^{th} sub-bias circuits comprises: a level conversion circuit, obtaining a high voltage bias control signal converting the signal level of the bias control signal received by itself from the signal level based on the low-power voltage into the signal level based on the high-power voltage, and generates the bias voltage having a voltage value based on the high voltage bias control signal.

2. The output amplifier circuit as claimed in claim 1, comprising:
a common bias voltage generation circuit, generating the common bias voltage in which a voltage value is fixed and supplying the common bias voltage to each of the amplifiers,
wherein, in each of the amplifiers, the operation current is set according to the bias voltage and the common bias voltage.

3. The output amplifier circuit as claimed in claim 1, wherein the bias control circuit individually transmits the bias control signal to the 1^{st} to K^{th} sub-bias circuits via 1^{st} to K^{th} wirings not in electrical contact with each other.

4. The output amplifier circuit as claimed in claim 1, wherein the amplifiers, the main bias circuit, the 1^{st} to K^{th} sub-bias circuits and the bias control circuit are formed on a single semiconductor IC chip,
the 1^{st} to K^{th} sub-bias circuits are arranged in a row along a side of the semiconductor IC chip, and
the main bias circuit and the bias control circuit are disposed at a central portion of the semiconductor IC chip.

5. A display driver, having:
a gradation voltage generation circuit, generating a plurality of gradation voltages respectively having voltage values corresponding to brightness levels of respective pixels based on a video signal; and
an output unit, comprising the output amplifier circuit as claimed in claim 1, and supplying the output voltages obtained by individually amplifying, as the input signals, the respective gradation voltages by using the amplifiers of the output amplifier circuit to a plurality of data lines of a display panel.

6. An output amplifier circuit, comprising:
a plurality of amplifiers, each receiving a predetermined high-power voltage and an input signal and generating an output voltage obtained by amplifying the input signal by using an operation current generated based on the high-power voltage;
a main bias circuit, generating a reference current having a predetermined constant current value;
1^{st} to K^{th} sub-bias circuits, provided respectively in correspondence with 1^{st} to K^{th} amplifier groups, K being an integer of 2 or more, obtained by dividing the amplifiers respectively into a predetermined quantity, generating bias voltages for setting magnitudes of the operation currents based on the high-power voltage, and supplying the bias voltage that is generated to each amplifier belonging to each of the 1^{st} to K^{th} amplifier groups; and
a bias control circuit, receiving a low-power voltage lower than the high-power voltage, generating a bias control signal indicating a voltage value of the bias voltage at a signal level based on the low-power voltage, and transmitting, via a wiring, the bias control signal that is generated to each of the 1^{st} to K^{th} sub-bias circuits,
wherein each of the 1^{st} to K^{th} sub-bias circuits comprises:
a level conversion circuit, having: an adjustment circuit, generating, as a first adjustment current, based on the low-power voltage, a current having a magnitude obtained by current-mirroring the reference current at a current mirror ratio based on the bias control signal; and a level conversion circuit comprising: a transistor that receives a predetermined clamp voltage at a gate of the transistor and converts the first adjustment current into a second adjustment current based on the high-power voltage; and
a current-voltage conversion circuit, generating, as the bias voltage, a voltage corresponding to a magnitude of the second adjustment current.

7. The output amplifier circuit as claimed in claim 6, comprising:
a common bias voltage generation circuit, generating the common bias voltage in which a voltage value is fixed and supplying the common bias voltage to each of the amplifiers,
wherein, in each of the amplifiers, the operation current is set by receiving the bias voltage and the common bias voltage.

8. The output amplifier circuit as claimed in claim 6, wherein the bias control circuit individually transmits the bias control signal to the 1^{st} to K^{th} sub-bias circuits via 1^{st} to K^{th} wirings not in electrical contact with each other.

9. The output amplifier circuit as claimed in claim 6, wherein the amplifiers, the main bias circuit, the 1^{st} to K^{th} sub-bias circuits and the bias control circuit are formed on a single semiconductor IC chip,
the 1^{st} to K^{th} sub-bias circuits are arranged in a row along a side of the semiconductor IC chip, and
the main bias circuit and the bias control circuit are disposed at a central portion of the semiconductor IC chip.

10. A display driver, having:
a gradation voltage generation circuit, generating a plurality of gradation voltages respectively having voltage values corresponding to brightness levels of respective pixels based on a video signal; and
an output unit, comprising the output amplifier circuit as claimed in claim 6, and supplying the output voltages obtained by individually amplifying, as the input signals, the respective gradation voltages by using the amplifiers of the output amplifier circuit to a plurality of data lines of a display panel.
